(19) United States
(12) Patent Application Publication
(10) Pub. No.: US 2026/0130161 A1
(43) Pub. Date: May 7, 2026

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Kuo-Ming WU, Tainan City (TW); Min-Chang CHING, Tainan (TW); Chung-Ying LIU, Hsinchu County (TW); Hau-Yi HSIAO, Chiayi City (TW); Chien-Ming WANG, Tainan City (TW); Che Wei YANG, New Taipei City (TW); Sheng-Chau CHEN, Tainan City (TW); Chung-Yi YU, Hsin-Chu (TW); Cheng-Yuan TSAI, Chu-Pei City (TW)

(21) Appl. No.: 18/939,904

(22) Filed: Nov. 7, 2024

(51) Int. Cl. H01L 21/67; H01L 21/56

(52) U.S. Cl. CPC H10P 72/0441; H10W 74/01

(57) ABSTRACT

A splash prevention system includes one or more devices that are configured to reduce the likelihood of errant sealant particles landing on a top and/or a bottom surface of a wafer stack during an edge sealing operation. An injector nozzle may dispense sealant into the groove around the wafer stack as a chuck is used to rotate the wafer stack. A vacuum device of the splash prevention system may provide a negative-pressure gas flow at the edge of the wafer stack, and the negative-pressure gas flow is used to collect errant sealant particles. Additionally and/or alternatively, an air curtain device may provide a positive-pressure gas flow at the edge of the wafer stack, and the positive-pressure gas flow may be used to dispel errant sealant particles away from the edge of the wafer stack.

### BACKGROUND

A three-dimensional integrated circuit (3DIC) assembly may include two or more integrated circuit (IC) dies that are stacked vertically and bonded along a bonding interface. The 3DIC assembly may be formed by stacking two or more semiconductor substrates, each including a subset of the two or more IC dies, using a wafer bonding operation such as a wafer-on-wafer (WoW) bonding operation. After the bonding operation, the 3DIC assembly including the two or more IC dies may be diced from the stack of two or more semiconductor substrates and encapsulated in a semiconductor die package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor processing tool described herein.

FIG. 2 illustrates an example implementation of an edge sealing operation described herein.

FIGS. 3A and 3B are diagrams of an example implementation of an air curtain device of a splash prevention system described herein.

FIGS. 4A-4C are diagrams of an example implementation of a vacuum device of a splash prevention system described herein.

FIG. 5 is a diagram of an example implementation of a vacuum device of a splash prevention system described herein.

FIG. 6 is a diagram of an example implementation of a vacuum device of a splash prevention system described herein.

FIG. 7 illustrates an example implementation of an edge sealing operation described herein.

FIG. 8 illustrates an example implementation of an edge sealing operation described herein.

FIG. 9 is a diagram of example components of a device described herein.

FIG. 10 is a flowchart of an example process associated with performing an edge sealing operation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a partially completed wafer stack of substrates (e.g., semiconductor wafers or another type of wafers) used to form a stacked integrated circuit die product may include a groove that corresponds to a beveled region around a perimeter of the wafer stack. The groove may be located between edges of the substrates in the wafer stack, and may occur because of incomplete bonding of the edges of the substrates and/or because of the edges of the substrates having a curvature, among other examples. In some cases, the groove around the perimeter of the wafer stack is filled with a sealant. The sealant prevents or reduces the likelihood of ingress of contaminants such as humidity, hydrogen, and/or oxygen from being exposed to the substrates through the groove. The sealant may also provide increased structural stability around the perimeter of the wafer stack, and may prevent or reduce the likelihood of cracking and/or delamination of the substrates that might otherwise originate at the groove.

The sealant may be dispensed into the groove around the wafer stack using a wafer edge sealing tool. The wafer stack may be placed on a chuck in a processing chamber of the wafer edge sealing tool, and an injector nozzle of the wafer edge sealing tool may dispense the sealant into the groove around the wafer stack as the chuck is used to rotate the wafer stack.

An amount of the sealant dispensed within the groove can impact the edge sealing performance of the sealant and can impact the yield of wafer stacks during manufacturing. For example, if the amount of the sealant dispensed into the groove is too little, a risk of delamination starting in the groove may be increased. Alternatively, if the amount of the sealant dispensed into the groove is too much, a risk of the sealant flowing out of the groove or splattering off of the edges of the substrates may increase. This may result in errant sealant particles (e.g., sealant particles that do not remain in the groove, sealant particles that correspond to overspray of the sealant that is dispensed in areas around the wafer stack) landing on the top and/or bottom surfaces of the wafer stack.

Errant sealant particles that land on the top and/or bottom surfaces of the wafer stack can cause contamination issues for integrated circuit die products formed on the substrates of the wafer stack, and can negatively impact subsequent semiconductor processes performed on the wafer stack. For example, a wafer grinding operation may be performed on the wafer stack (e.g., after the groove around the wafer stack is sealed) to thin down the substrates in preparation for additional processing. Errant sealant particles that land on the top and/or bottom surfaces of the wafer stack can cause defects to occur during the wafer grinding operation, such as bending and/or cracking in the edges of the substrates. This may result in integrated circuit die products formed from the wafer stack being scrapped (or the entire wafer stack being scrapped), resulting in reduced yield of integrated circuit die products.

In some implementations described herein, a splash prevention system for use with a wafer edge sealing tool includes one or more devices that are configured to prevent, minimize, and/or reduce the likelihood of errant sealant particles landing on a top and/or a bottom surface of a wafer stack during an edge sealing operation. The wafer stack may be placed on a chuck in a processing chamber of the wafer edge sealing tool, and an injector nozzle of the wafer edge sealing tool may dispense the sealant into the groove around the wafer stack as the chuck is used to rotate the wafer stack. While the sealant is being dispensed into the groove, a vacuum device of the splash prevention system may provide a negative-pressure gas flow at the edge of the wafer stack, and the negative-pressure gas flow is used to collect errant sealant particles before the errant sealant particles land on the top and/or the bottom surface of the wafer stack. Additionally and/or alternatively, while the sealant is being dispensed into the groove, an air curtain device may provide a positive-pressure gas flow at the edge of the wafer stack, and the positive-pressure gas flow may be used to dispel errant sealant particles away from the edge of the wafer stack before the errant sealant particles land on the top and/or the bottom surface of the wafer stack. In this way, the negative-pressure gas flow provided by the vacuum device of the splash prevention system and/or the positive-pressure gas flow provided by the air curtain device of the splash prevention system reduce the likelihood of (and/or the amount of) sealant particles landing on the top and/or the bottom surfaces of the wafer stack. This reduces the likelihood of formation of defects in the integrated circuit die product formed on the substrates of the wafer stack, and/or reduces the likelihood of process defects occurring in subsequent processes performed for the wafer stack. Accordingly, the splash prevention system described herein may increase the yield of integrated circuit die products formed on the substrates of the wafer stack.

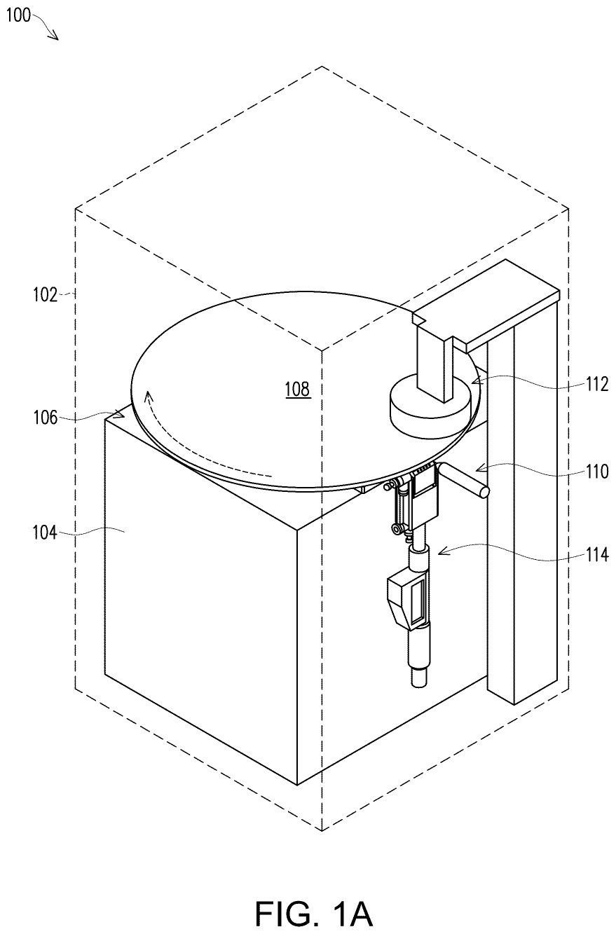

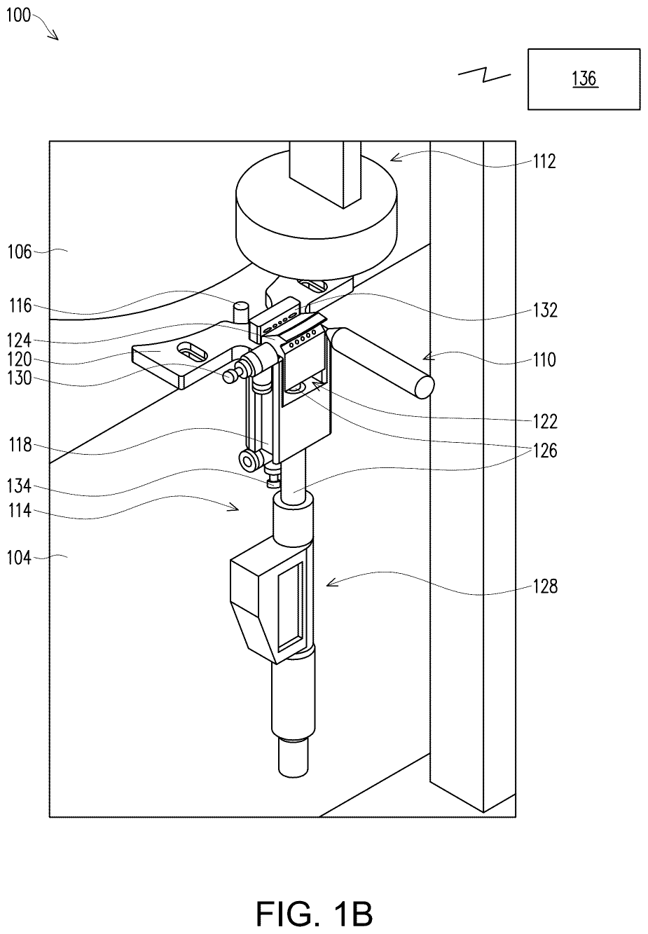

FIGS. 1A and 1B are diagrams of an example semiconductor processing tool 100 described herein. The semiconductor processing tool 100 includes a wafer edge sealing tool or another type of semiconductor processing tool that is configured to dispense a sealant in a groove around a perimeter of a wafer stack.

As shown in a perspective view in FIG. 1A, the semiconductor processing tool 100 may include a processing chamber 102 and a base 104 within the processing chamber 102. The base 104 may correspond to a housing in which various systems, subsystems, and/or devices, of the semiconductor processing tool 100 are located, such as plumbing, pumps, electrical systems, controllers, actuators such as motors, and/or other components. The base 104 may also support a chuck 106 of the semiconductor processing tool 100. The chuck 106 may be located within the processing chamber 102 and may be configured to support a wafer stack 108. The wafer stack 108 (not part of the semiconductor processing tool 100) may be positioned on the chuck 106, and the chuck 106 may secure the wafer stack 108 in place using a vacuum force (in implementations in which the chuck 106 is a vacuum chuck), an electrostatic force (in implementations in which the chuck 106 is an electrostatic chuck (ESC)), and/or another type of force.

The wafer stack 108 is secured to the chuck 106 so that the chuck 106 can rotate the wafer stack 108 in a secure manner while an injector nozzle 110 of the semiconductor processing tool 100 injects a sealant into a groove around the edge of the wafer stack 108. Rotating the wafer stack 108 while injecting the sealant into the groove enables the sealant to be dispensed around the full circumference or perimeter of the wafer stack 108. In some implementations, the chuck 106 is configured to rotate the wafer stack 108 at a rate of approximately 50 degrees per second to approximately 70 degrees per second. However, other values and ranges are within the scope of the present disclosure.

In some implementations, the injector nozzle 110 may be coupled to a pump system (e.g., that may be included in the base 104 or external to the processing chamber 102) having an adjustable pressure and/or dispense rate. This enables the dispensing rate of sealant to be adjusted. Furthermore, and in some implementations, the injector nozzle 110 is coupled to a positioning system that can be used to adjust an aim point of the injector nozzle 110 for dispensing sealant. The injector nozzle 110 may dispense sealant along an axis that is approximately parallel to top and bottom surfaces of the wafer stack 108.

In some implementations, the injector nozzle 110 may be positioned approximately 1 millimeter to approximately 2 millimeters away from the edge of the wafer stack 108. However, other values and ranges are within the scope of the present disclosure. In some implementations, the injector nozzle 110 may be configured to dispense sealant at a frequency of approximately 10 microseconds to approximately 15 microsections. However, other values and ranges are within the scope of the present disclosure. In some implementations, injector nozzle 110 may be configured to dispense sealant at a rate of approximately 7 micrograms per degree of turn to approximately 8 micrograms per degree of turn. However, other values and ranges are within the scope of the present disclosure.

As further shown in FIG. 1A, in some implementations, a monitoring device 112 may be included in and/or mounted to the processing chamber 102. The monitoring device 112 may include a camera device (e.g., a charge coupled device (CCD) camera, a complementary metal-oxide-semiconductor (CMOS) image sensor) that is configured to generate images and/or video for monitoring edge sealing operations that are performed in the processing chamber 102 of the semiconductor processing tool 100. In some implementations, the monitoring device 112 is omitted from the semiconductor processing tool 100.

As further shown in FIG. 1A, a splash prevention system 114 may be coupled to the semiconductor processing tool 100. The splash prevention system 114 is configured to prevent, minimize, and/or reduce the likelihood of sealant splashing onto the top and/or bottom surfaces of the wafer stack 108 during an edge sealing operation performed in the processing chamber 102. The splash prevention system 114 may be configured to be mounted (e.g., permanently mounted, removably mounted) to the base 104 of the semiconductor processing tool 100 near the injector nozzle 110.

FIG. 1B illustrates a detailed view of the splash prevention system 114. As shown in FIG. 1B, the splash prevention system 114 may be mounted to a top surface of the base 104 of the semiconductor processing tool 100. The splash prevention system 114 may be fitted around a lift pin 116 of the semiconductor processing tool 100 and around the chuck 106 so as to not interfere with the operation of the chuck 106 and the lift pin 116. Additional lift pins (not shown) may be included around the chuck, and the lift pins (including the lift pin 116) may be configured to lower a wafer stack 108 onto the chuck 106 and/or to lift a wafer stack 108 off of the chuck 106.

The splash prevention system 114 may include a main body 118 and a mounting flange 120 coupled to the main body 118. The mounting flange 120 may have a cutout for the lift pin 116 and may have a curved side that conforms to the curvature of the chuck 106. In some implementations, the mounting flange 120 is oriented at an approximately orthogonal angle relative to the main body 118 so that the main body 118 can rest against a side of the base 104. However, other angles between the mounting flange 120 and the main body 118 are within the scope of the present disclosure.

The main body 118 may include a recess 122 (or pocket) in which a vacuum device 124 of the splash prevention system 114 is situated. The vacuum device 124 may be configured to be moveable within the recess 122, such as movable in a vertical direction. The vacuum device 124 may be coupled to an adjustment member 126 that extends through the main body 118 and into the recess 122. The adjustment member 126 may include a shaft and/or another type of member that is capable of moving the vacuum device 124 vertically into and/or out of the recess 122 so as to adjust the vertical position of the vacuum device 124. In some implementations, a display device 128 may be coupled to the adjustment member 126, and the display device 128 may be configured to generate a visual display of a vertical position of the vacuum device 124 and/or a visual display of a distance between the vacuum device 124 and a bottom surface of a wafer stack 108 on the chuck 106, among other examples.

The vacuum device 124 may be configured to provide a negative-pressure gas flow (e.g., a vacuum) at the edge of a wafer stack 108 on the chuck 106. The negative-pressure gas flow may be provided near the injector nozzle 110 so that the negative-pressure gas flow pulls or sucks errant sealant particles into the vacuum device 124 before the errant sealant particles land on the top and/or the bottom surface of the wafer stack 108. The negative-pressure gas flow may be generated by applying a negative pressure through a gas outlet 130 coupled to a side of (or another location of) the vacuum device 124. The negative pressure may be generated by a vacuum pump (not shown) and/or another type of pump. The vacuum pump may be coupled directly to the gas outlet 130, or may be indirectly coupled to the gas outlet 130 by a hose.

As further shown in FIG. 1B, the splash prevention system 114 may include an air curtain device 132. The air curtain device 132 may be coupled to the main body 118 of the splash prevention system 114, and/or to a portion of the mounting flange 120. In some implementations, the air curtain device 132 is mounted to the mounting flange 120 in a fixed position and extends vertically upward from the mounting flange 120. In some implementations, the air curtain device 132 is mounted to the mounting flange 120, and the position of the air curtain device 132 may be adjusted.

The air curtain device 132 may be configured to provide a positive-pressure gas flow (e.g., a positive gas flow) at the edge of a wafer stack 108 on the chuck 106. The positive-pressure gas flow may be provided near the injector nozzle 110 and may function as an air curtain in that the positive-pressure gas flow pushes or dispels errant sealant particles away from the wafer stack 108 before the errant sealant particles land on the top and/or the bottom surface of the wafer stack 108. In other words, the positive-pressure gas flow creates a curtain (or wall) of a gas flow that blocks the errant sealant particles from, for example, traveling toward the bottom surface of the wafer stack 108.

The positive-pressure gas flow may be generated by applying a positive pressure through a gas inlet 134 coupled to the main body 118 of the splash prevention system 114. In some implementations, the positive pressure is generated by a compressor (not shown) that generates compressed gas that is provided to the air curtain device 132 through the gas inlet 134 (e.g., directly or through a hose). The compressed gas may be provided directly or may be stored in and provided from a compressed-gas tank. In some implementations, the positive pressure is generated by a fan that blows gas into the air curtain device 132 through the gas inlet 134. The gas (or the compressed gas) may include atmospheric air, an inert gas such as nitrogen (N₂), and/or another type of gas.

As further shown in FIG. 1B, the splash prevention system 114 may include a controller 136. The controller 136 may be a dedicated component of the splash prevention system 114 (e.g., the controller 136 is specifically for controlling the splash prevention system 114), or the controller 136 may be a part of the semiconductor processing tool 100 that performs controller operations for the semiconductor processing tool 100 as well as the splash prevention system 114.

The controller 136 (e.g., a processor, a combination of a processor and memory, among other examples) may be communicatively coupled to one or more components of the semiconductor processing tool 100 and/or of the splash prevention system 114, such as electrical sources, mass flow controllers vacuum pumps, compressors, the chuck 106, the monitoring device 112, the lift pin 116 (and other lift pins), and/or the adjustment member 126, among other examples. The controller 136 may communicate with these components on one or more wireless communication links, one or more wired communication links, and/or a combination of wireless and wired communication links.

The controller 136 may be configured to control the operation of one or more components of the semiconductor processing tool 100 and/or of the splash prevention system 114. For example, the controller 136 may be configured to provide signals to the lift pin 116 (and other lift pins around the chuck 106) to lower a wafer stack 108 onto the chuck 106 and/or to lift a wafer stack 108 off of the chuck 106. As another example, the controller 136 may be configured to provide signals to chuck 106 to cause the chuck 106 to rotate a wafer stack 108 positioned on the chuck 106. As another example, the controller 136 may be configured to provide signals to one or more pumps to cause a sealant to be dispensed through the injector nozzle 110 and into a groove around a perimeter of a wafer stack 108 positioned on the chuck 106 (e.g., while the chuck 106 rotates the wafer stack 108).

As another example, the controller 136 may be configured to provide signals to a vacuum pump to generate a negative-pressure gas flow (e.g., a vacuum pressure) through the vacuum device 124 to pull or suck errant particles away from a top and/or a bottom surface of wafer stack 108 and into the vacuum device 124. As another example, the controller 136 may be configured to provide signals to a compressor to cause a positive-pressure gas flow to be provided through the air curtain device 132 and toward an edge of a wafer stack 108 to push or blow errant sealant particles away from the edge of the wafer stack 108 (e.g., before the errant sealant particles land on a top and/or on a bottom surface of the wafer stack 108). As another example, the controller 136 may be configured to provide signals to the adjustment member 126 to cause the adjustment member 126 to adjust a vertical position of the vacuum device 124. As another example, the controller 136 may be configured to receive signals from the monitoring device 112 corresponding to images and/or video generated by the monitoring device 112.

As indicated above, FIGS. 1A and 1B are provided as an example. Other examples may differ from what is described with regard to FIGS. 1A and 1B.

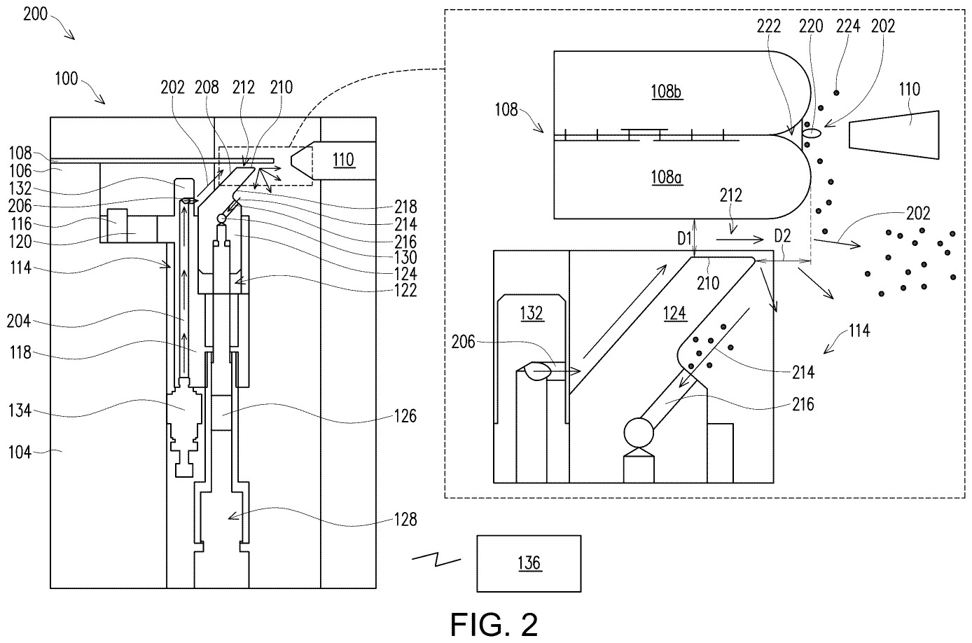

FIG. 2 illustrates an example implementation 200 of an edge sealing operation described herein. The edge sealing operation may be performed using the semiconductor processing tool 100 described herein. The edge sealing operation may be performed to dispense a sealant into a groove around a perimeter of a wafer stack 108 positioned on a chuck 106 in a processing chamber 102 of the semiconductor processing tool 100.

As shown in FIG. 2, prior to and/or during the edge sealing operation, a positive-pressure gas flow 202 may be generated and provided through the air curtain device 132 to an edge of the wafer stack 108. The positive-pressure gas flow 202 may be provided from the gas inlet 134 through a gas supply line 204 in the main body 118 of the splash prevention system, and out through one or more air holes 206 in the air curtain device 132.

The air curtain device 132 may be positioned adjacent to the vacuum device 124 such that the air hole(s) 206 of the air curtain device 132 are facing a backside surface 208 of the vacuum device 124. Thus, the positive-pressure gas flow 202 may flow out of the air hole(s) 206 and along the backside surface 208 of the vacuum device 124 toward the bottom surface of the wafer stack 108. The backside surface 208 of the vacuum device 124 may be angled relative to the air curtain device 132, which promotes the flow of the positive-pressure gas flow 202 along the backside surface 208 and reduces the amount of the positive-pressure gas flow 202 that is deflected toward the center of the wafer stack 108. Thus, the backside surface 208 functions as a baffle (e.g., a baffle device) that directs the positive-pressure gas flow 202 toward a top surface 210 of the vacuum device 124.

The top surface 210 of the vacuum device 124 is positioned adjacent to the bottom surface of the wafer stack 108. The positive-pressure gas flow 202 flows through a gap 212 between the top surface of the vacuum device 124 and the bottom surface of the wafer stack 108, and may flow from the gap 212 outward away from the perimeter of the wafer stack 108.

As further shown in FIG. 2, prior to and/or during the edge sealing operation, a negative-pressure gas flow 214 may be generated through the one or more vacuum holes 216 of the vacuum device 124. The negative-pressure gas flow 214 may pull errant sealant particles into the vacuum hole(s) 216 of the vacuum device 124 before the errant sealant particles propagate through the gap 212 and land on the bottom surface of the wafer stack 108. A frontside surface 218 of the vacuum device 124 may direct the errant sealant particles captured by the negative-pressure gas flow 214 toward the vacuum hole(s) 216 and may inhibit the errant sealant particles from propagating toward the center of the wafer stack 108.

As shown in a closeup view in FIG. 2, the injector nozzle 110 may dispense a sealant 220 into a groove 222 (or beveled region) around a perimeter of the wafer stack 108. The injector nozzle 110 may dispense the sealant 220 into the groove 222 around the perimeter of the wafer stack 108 while the chuck 106 rotates the wafer stack 108 so that the sealant 220 is dispensed into the groove 222 across the entire perimeter or circumference of the wafer stack 108.

The groove 222 may correspond to a region around the perimeter where stacked substrates 102a and 102b of the wafer stack 108 are joined or bonded together. In other words, the groove 222 may correspond to a bonding interface between the substrates 102a and 102b of the wafer stack 108. The groove 222 may result from incomplete bonding between the edges of the substrates 102a and 102b, and/or due to curvature in the edges of the substrates 102a and/or 102b. The injector nozzle 110 may be used to dispense the sealant 220 into the groove 222 to seal the groove 222, which protects the substrates 102a and 102b from ingress of contaminants through the groove 222 and/or reduces the likelihood of delamination of the substrates 102a and 102b starting from the groove 222.

The substrates 102a and 102b may each include a plurality of integrated circuit die products that are bonded together to form 3DIC assemblies. In some implementations, the substrates 102a and 102b include the same type or types of integrated circuit die products. For example, the substrates 102a and 102b may each include high-bandwidth memory dies (HBM dies) that are bonded together in a vertically stacked arrangement. In some implementations, the substrates 102a and 102b include different types of integrated circuit die products. For example, the substrate 102a may include logic dies and the substrate 102b may include memory dies, where the logic dies and the memory dies are bonded together in a vertically stacked arrangement. As another example, the substrate 102a may include CMOS image sensor dies and the substrate 102b may include application-specific integrated circuit (ASIC) dies, where the CMOS image sensor dies and the ASIC dies are bonded together in a vertically stacked arrangement.

The sealant 220 may include a low-viscosity material such as a dimethyldiethoxysilane (DMDEOS) compound, a tetraethyl orthosilicate (TEOS) compound, a polydimethylsiloxane (PDMS) compound, or a polysilazanes (PHPS) compound. In some implementations, the sealant 220 may include composite filler particulates such as silicon carbide (SiC) composite filler particulates, aluminum dioxide (Al₂O₃) composite filler particulates, zirconium tungsten phosphate (Zr₂WP₂O₁₂ or ZWP) composite filler particulates, silica (SiO₂) composite filler particulates, and/or ceramic composite particulates. Such composite filler particulates may improve a robustness of the sealant 220 and reduce a likelihood of tearing within the sealant 220.

As further shown in the closeup view in FIG. 2, errant sealant particles 224 may occur around the edge of the wafer stack 108. The errant sealant particles 224 may correspond to particles of the sealant 220 that are not deposited in the groove 222 and/or that are deposited in the groove 222 and subsequently become airborne (e.g., that are not retained in the groove 222). In some implementations, errant sealant particles 224 may range in size (e.g., diameter) from approximately 0.4 millimeters to approximately 0.8 millimeters. However, some errant sealant particles 224 may be less than approximately 0.4 millimeters in size, and some errant sealant particles 224 may be greater than approximately 0.8 millimeters in size.

The positive-pressure gas flow 202 provided from the air curtain device 132 pushes or dispels the errant sealant particles 224 away from the wafer stack 108 so that the errant sealant particles 224 do not land on the top and/or on the bottom surfaces of the wafer stack 108. In some implementations, the positive-pressure gas flow 202 may be provided outward from the edge of the wafer stack 108 at a flow rate that is included in a range of approximately 6000 standard cubic centimeters per minute (sccm) to approximately 8000 sccm to sufficiently dispel errant sealant particles 224 away from the wafer stack 108. However, other values and ranges are within the scope of the present disclosure. In some implementations, the positive-pressure gas flow 202 may be provided outward from the edge of the wafer stack 108 at a flow rate that is greater than approximately 8000 sccm.

In some implementations, the controller 136 determines the flow rate for the positive-pressure gas flow 202 using a machine learning model. The machine learning model may include and/or may be associated with one or more of a neural network model, a random forest model, a clustering model, or a regression model. In some implementations, the controller 136 uses the machine learning model to determine the flow rate for the positive-pressure gas flow 202 by analyzing the flow pattern of errant sealant particles 224 at the edge or perimeter of the wafer stack 108 using the machine learning model, and to select a flow rate for the positive-pressure gas flow 202 and a likelihood, probability, or confidence that a particular outcome (e.g., a desired flow pattern for the errant sealant particles 224) will be achieved using the flow rate for the positive-pressure gas flow 202.

The controller 136 (or another system) may train, update, and/or refine the machine learning model to increase the accuracy of the outcomes and/or parameters determined using the machine learning model. The controller 136 may train, update, and/or refine the machine learning model based on feedback and/or results from the edge sealing operation, as well as from historical or related edge sealing operations (e.g., from hundreds, thousands, or more historical or related edge sealing operations) performed by the semiconductor processing tool 100.

Providing the positive-pressure gas flow 202 through the gap 212 between the top surface 210 of the vacuum device 124 and the bottom surface of the wafer stack 108 enables the errant sealant particles 224 at the edge of the wafer stack 108 to be coherent and tightly controlled. Without the vacuum device 124 functioning as a baffle device, the errant sealant particles 224 may be turbulent and incoherent, resulting in an increased likelihood that the errant sealant particles 224 might otherwise interfere with the flow of the sealant 220 from the injector nozzle 110 to the groove 222.

The negative-pressure gas flow 214 generated from the vacuum device 124 pulls or sucks errant sealant particles 224 away from the wafer stack 108 and into the vacuum hole(s) 216 so that the errant sealant particles 224 do not land on the top and/or on the bottom surfaces of the wafer stack 108. In some implementations, some errant sealant particles 224 not dispelled by the positive-pressure gas flow 202 are captured by the negative-pressure gas flow 214 and directed into the vacuum hole(s) 216. In some implementations, some errant sealant particles 224 are dispelled by the positive-pressure gas flow 202 and are then captured by the negative-pressure gas flow 214 and directed into the vacuum hole(s) 216.

In some implementations, the negative-pressure gas flow 214 may be provided at a negative pressure that is included in a range of approximately −200 pascals to approximately −600 pascals to sufficiently capture errant sealant particles 224 without interfering with the flow of the sealant 220 from the injector nozzle 110 to the groove 222. However, other values and ranges are within the scope of the present disclosure.

In some implementations, the controller 136 determines the negative pressure for the negative-pressure gas flow 214 using a machine learning model. The machine learning model may include and/or may be associated with one or more of a neural network model, a random forest model, a clustering model, or a regression model. In some implementations, the controller 136 uses the machine learning model to determine the negative pressure for the negative-pressure gas flow 214 by analyzing the flow pattern of errant sealant particles 224 at the edge or perimeter of the wafer stack 108 using the machine learning model, and to select a negative pressure for the negative-pressure gas flow 214 and a likelihood, probability, or confidence that a particular outcome (e.g., a desired flow pattern for the errant sealant particles 224) will be achieved using the negative pressure for the negative-pressure gas flow 214.

The controller 136 (or another system) may train, update, and/or refine the machine learning model to increase the accuracy of the outcomes and/or parameters determined using the machine learning model. The controller 136 may train, update, and/or refine the machine learning model based on feedback and/or results from the edge sealing operation, as well as from historical or related edge sealing operations (e.g., from hundreds, thousands, or more historical or related edge sealing operations) performed by the semiconductor processing tool 100.

As indicated above, the adjustment member 126 may be configured to adjust a vertical position of the vacuum device 124. The adjustment of the vertical position of the vacuum device 124 may result in an adjustment in the distance between the top surface 210 of the vacuum device 124 and the bottom surface of the wafer stack 108 (indicated in FIG. 2 as dimension D1). The distance between the top surface 210 of the vacuum device 124 and the bottom surface of the wafer stack 108 may be adjusted to achieve a sufficient positive-pressure gas flow 202 toward the edge of the wafer stack 108 while minimizing the flow of errant sealant particles 224 inward toward the center of the wafer stack 108. In some implementations, the distance between the top surface 210 of the vacuum device 124 and the bottom surface of the wafer stack 108 may be adjusted to be greater than 0 millimeters and up to approximately 15 millimeters. However, other values and ranges are within the scope of the present disclosure.

In some implementations, the distance between the top surface 210 of the vacuum device 124 and the bottom surface of the wafer stack 108 may be adjusted during an edge sealing operation (e.g., while the sealant 220 is dispensed into the groove 222 of the wafer stack 108). For example, the monitoring device 112 may be used to monitor the performance of the splash prevention system 114 during the edge sealing operation, and the distance between the top surface 210 of the vacuum device 124 and the bottom surface of the wafer stack 108 may be adjusted based on the performance of the performance of the splash prevention system 114 during the edge sealing operation. For example, the controller 136 may determine, based on images and/or video generated by the monitoring device 112, that a rate (or a quantity) of errant sealant particles 224 passing through the gap 212 satisfies a threshold rate (or a threshold quantity). The controller 136 may provide one or more signals to the adjustment member 126 to decrease the distance between the top surface 210 of the vacuum device 124 and the bottom surface of the wafer stack 108 based on determining that the rate (or the quantity) of errant sealant particles 224 passing through the gap 212 satisfies the threshold rate (or the threshold quantity).

In some implementations, the controller 136 determines the adjustments to the distance (e.g., the dimension D1) using a machine learning model. The machine learning model may include and/or may be associated with one or more of a neural network model, a random forest model, a clustering model, or a regression model. In some implementations, the controller 136 uses the machine learning model to determine the distance by analyzing the flow pattern of errant sealant particles 224 at the edge or perimeter of the wafer stack 108, and using the machine learning model to select a distance and a likelihood, probability, or confidence that a particular outcome (e.g., a desired flow pattern for the errant sealant particles 224) will be achieved using the distance.

The controller 136 (or another system) may train, update, and/or refine the machine learning model to increase the accuracy of the outcomes and/or parameters determined using the machine learning model. The controller 136 may train, update, and/or refine the machine learning model based on feedback and/or results from the edge sealing operation, as well as from historical or related edge sealing operations (e.g., from hundreds, thousands, or more historical or related edge sealing operations) performed by the semiconductor processing tool 100.

As further shown in the closeup view in FIG. 2, the vacuum device 124 may be located inward from the perimeter or edge of the wafer stack 108 by a distance (indicated in FIG. 2 as dimension D2). In some implementations, the distance may be greater than 0 millimeters and up to approximately 15 millimeters. However, other ranges and values are within the scope of the present disclosure.

As indicated above, FIG. 2 is provided as an example. Other examples may differ from what is described with regard to FIG. 2.

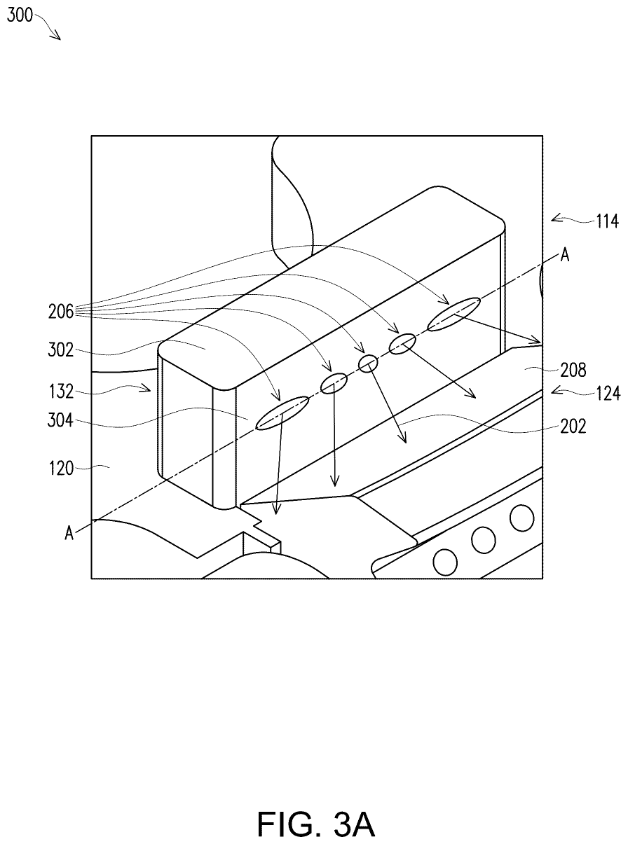

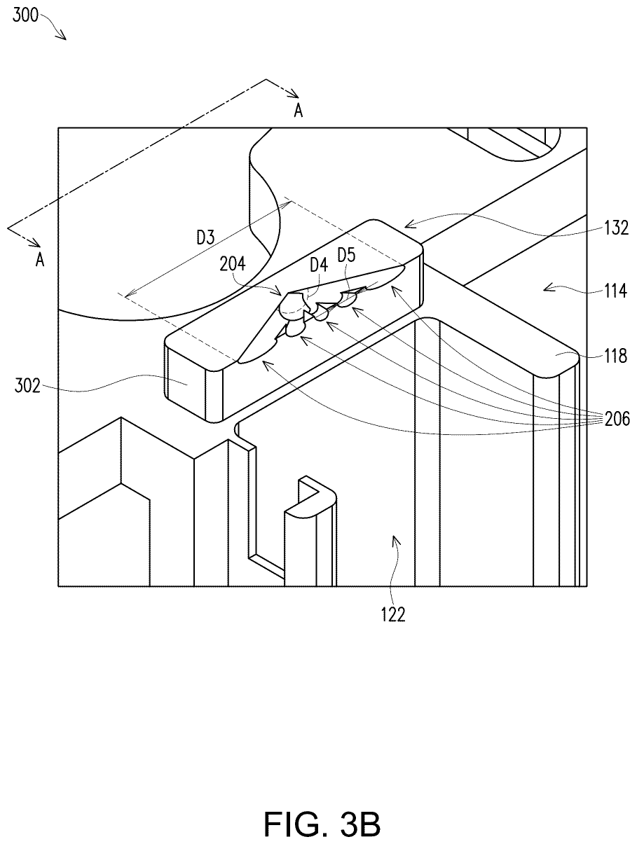

FIGS. 3A and 3B are diagrams of an example implementation 300 of the air curtain device 132 of the splash prevention system 114 described herein. As shown in FIG. 3A, the air curtain device 132 may include a main body 302 that extends from the mounting flange 120. The air curtain device 132 includes one or more air holes 206 that are located in a frontside surface 304 of the main body 302. The frontside surface 304 and the air hole(s) 206 may be oriented such that the frontside surface 304 and the air hole(s) 206 are facing the backside surface of the vacuum device 124. In some implementations, the air curtain devices 132 includes a plurality of air holes 206 that are laterally distributed across the frontside surface 304 of the air curtain device 132, and the plurality of air holes 206 distribute the positive-pressure gas flow 202 across the backside surface 208 of the vacuum device 124.

FIG. 3B illustrates a cross-section view of the air curtain device 132 along the line A-A in FIG. 3A. The cross-section view in FIG. 3B illustrates additional details of the air holes 206. As shown in FIG. 3B, the air holes 206 may extend from the gas supply line 204 in the main body 302 to the frontside surface 304. The air holes 206 may be distributed across a distance (dimension D3) that may be included in a range of approximately 10 millimeters to approximately 15 millimeters. However, other values and ranges are within the scope of the present disclosure.

As further shown in FIG. 3B, the air holes 206 being laterally distributed across the frontside surface 304 and originating from the gas supply line 204 results in at least a subset of the air holes 206 extending at an angle relative to the frontside surface 304. The air holes 206 may span a distribution angle (dimension D4) that is included in a range of approximately 100 degrees to approximately 140 degrees. However, other values and ranges are within the scope of the present disclosure.

As further shown in FIG. 3B, an air hole 206 may have a width (dimension D5) that is included in a range of approximately 1 millimeter to approximately 2 millimeters. However, other values and ranges are within the scope of the present disclosure.

In some implementations, as opposed to having separate air holes 206 in the frontside surface 304 of the air curtain device 132, the air curtain device 132 may include a single elongated air hole 206 that spans the dimension D3 and has outer sides that are angled according to the dimension D4.

As indicated above, FIGS. 3A and 3B are provided as an example. Other examples may differ from what is described with regard to FIGS. 3A and 3B.

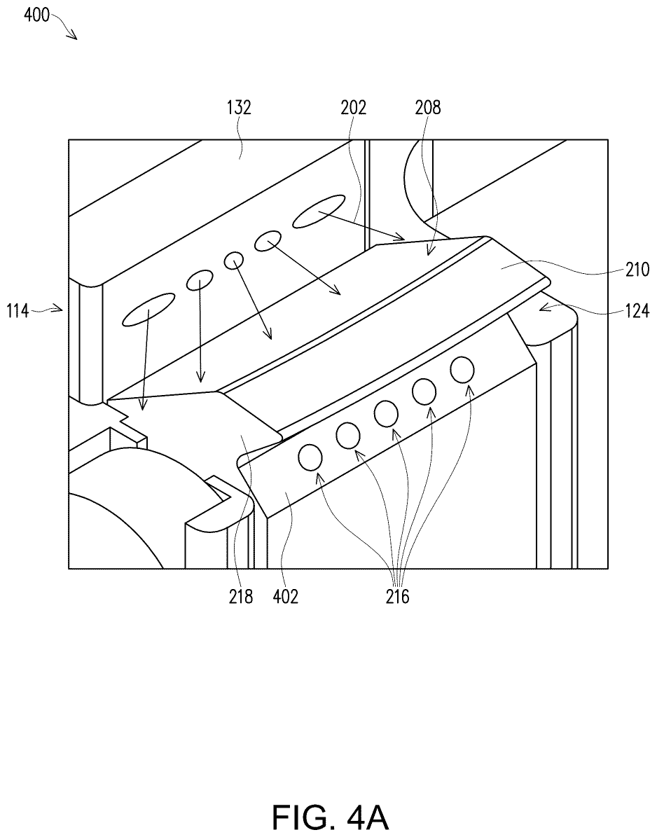

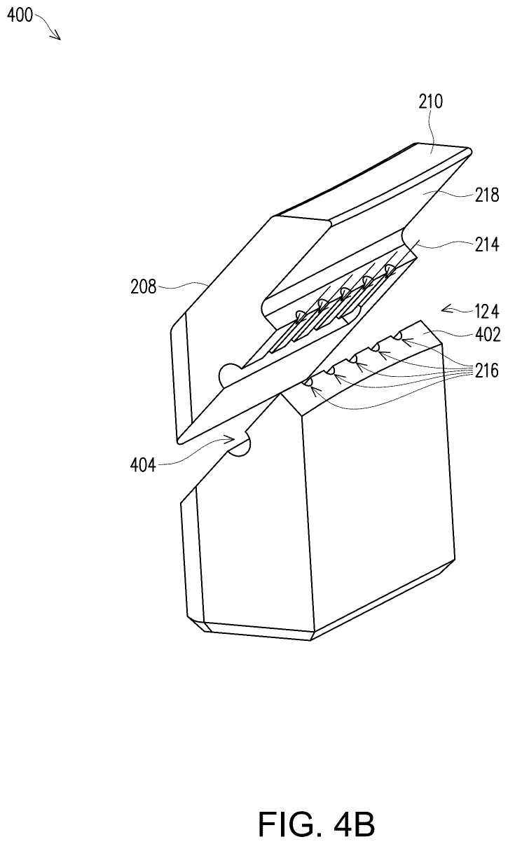

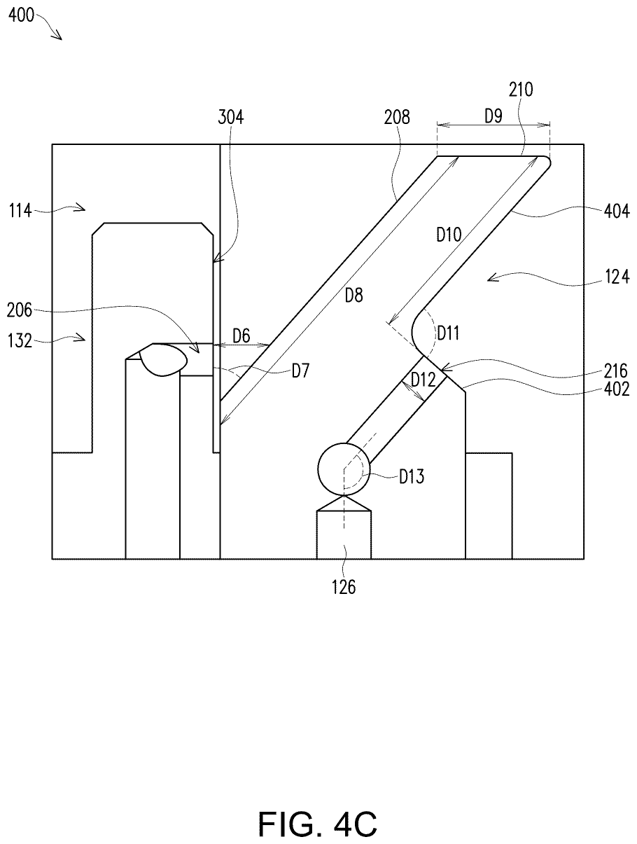

FIGS. 4A-4C are diagrams of an example implementation 400 of the vacuum device 124 of the splash prevention system 114 described herein. As shown in FIG. 4A, the backside surface 208 of the vacuum device 124 may be configured to receive the positive-pressure gas flow 202 from the air curtain device 132. The positive-pressure gas flow 202 may flow along the backside surface 208 and toward the top surface 210 of the vacuum device 124.

As further shown in FIG. 4A, the vacuum device 124 may further include a shelf 402 that is adjacent to the frontside surface 218 of the vacuum device 124. The vacuum hole(s) 216 may be located in and may extend through the shelf 402. In some implementations, the vacuum device 124 includes a plurality of vacuum holes 216 that are laterally distributed across the shelf 402.

FIG. 4B illustrates a detailed view of the vacuum holes 216. While FIG. 4B illustrates an exploded view of the vacuum device 124, the vacuum device 124 is not necessarily a 2-piece structure and may instead be a one-piece structure. As shown in FIG. 4B, the vacuum holes 216 may extend through the shelf 402 and to a common rail 404. The common rail 404 is a gas line that is in fluid communication with each of the vacuum holes 216. The common rail 404 may also be referred to as a manifold. The common rail 404 may be coupled to the gas outlet 130 (not shown). In some implementations, an end of the common rail 404 is threaded so that the gas outlet 130 can be screwed into the common rail 404.

In some implementations, the vacuum holes 216 extend in a direction that is approximately perpendicular to a direction in which the common rail 404 extends. In some implementations, the vacuum holes 216 extend in a direction that is oriented at another angle relative to the common rail 404.

FIG. 4C illustrates various example dimensions of the vacuum device 124. An example dimension D6 corresponds to a distance between the frontside surface 304 of the air curtain device 132 and the backside surface 208 of the vacuum device 124. In some implementations, the dimension D6 is included in a range of approximately 3 millimeters to approximately 4 millimeters to provide sufficient airflow and to minimize backflow of the positive-pressure gas flow 202. However, other values and ranges are within the scope of the present disclosure.

Another example dimension D7 includes an angle between the frontside surface 304 of the air curtain device 132 and the backside surface 208 of the vacuum device 124. In some implementations, the dimension D7 is an acute angle (e.g., less than 90 degrees) and is included in a range of approximately 30 degrees to approximately 60 degrees, which promotes the flow of the positive-pressure gas flow 202 along the backside surface 208 and reduces the amount of the positive-pressure gas flow 202 that is deflected toward the center of the wafer stack 108. However, other values and ranges are within the scope of the present disclosure.

Another example dimension D8 includes a length of the backside surface 208 of the vacuum device 124. In some implementations, the dimension D8 is included in a range of approximately 10 millimeters to approximately 15 millimeters. However, other values and ranges are within the scope of the present disclosure.

Another example dimension D9 includes a length of the top surface 210 of the vacuum device 124. In some implementations, the dimension D9 is included in a range of approximately 3 millimeters to approximately 7 millimeters. However, other values and ranges are within the scope of the present disclosure.

Another example dimension D10 includes a length of the frontside surface 218 of the vacuum device 124. In some implementations, the dimension D10 is included in a range of approximately 4 millimeters to approximately 7 millimeters. However, other values and ranges are within the scope of the present disclosure.

Another example dimension D11 includes an angle between the frontside surface 218 of the vacuum device 124 and the shelf 402 of the vacuum device 124. In some implementations, the dimension D11 is included in a range of approximately 80 degrees to approximately 110 degrees. However, other values and ranges are within the scope of the present disclosure.

Another example dimension D12 includes a width (or diameter) of a vacuum hole 216. In some implementations, the dimension D12 is included in a range of approximately 1 millimeter to approximately 3 millimeters. However, other values and ranges are within the scope of the present disclosure.

In some implementations, as opposed to having separate vacuum holes 216 in the shelf 402 of the vacuum device 124, the vacuum device 124 may include a single elongated vacuum hole 216 that spans across at least a portion of the shelf 402.

Another example dimension D13 includes an angle between a vacuum hole 216 and the adjustment member 126 coupled to the vacuum device 124. In some implementations, the dimension D13 is included in a range of approximately 120 degrees to approximately 150 degrees. However, other values and ranges are within the scope of the present disclosure.

As indicated above, FIGS. 4A-4C are provided as an example. Other examples may differ from what is described with regard to FIGS. 4A-4C.

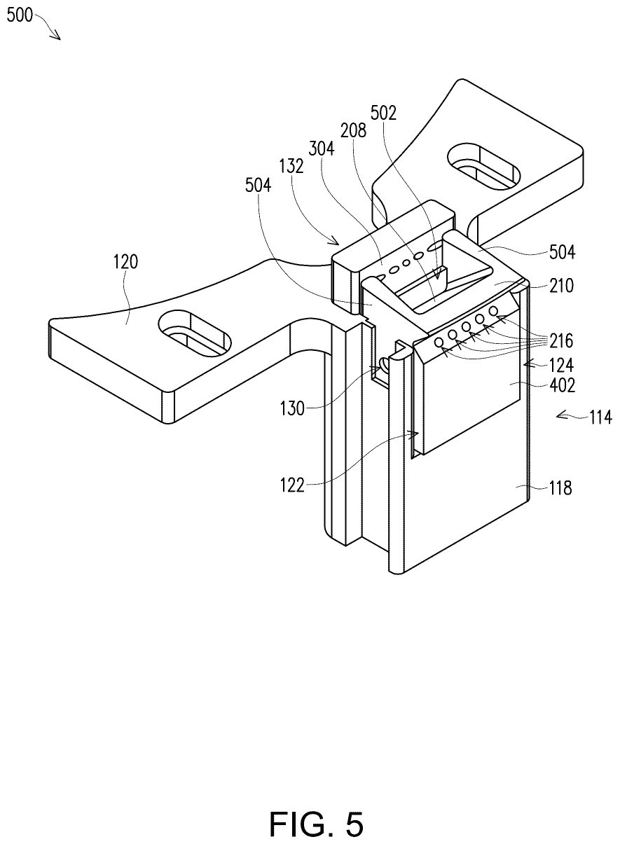

FIG. 5 is a diagram of an example implementation 500 of the vacuum device 124 of the splash prevention system 114 described herein. As shown in FIG. 5, the example implementation 500 of the vacuum device 124 is similar to the example implementation 400 of the vacuum device 124 illustrated in FIG. 4A-4C. However, the example implementation 500 of the vacuum device 124 includes an air baffle 502 defined by the backside surface 208 of the vacuum device 124 and sidewalls 504 of the vacuum device 124 through which the positive-pressure gas flow 202 is to flow.

The sidewalls 504 may be located on opposing sides of the backside surface 208 of the vacuum device 124 and may be coupled to the backside surface 208. The sidewalls 504 extend away from the backside surface 208 and toward a frontside surface 304 of the air curtain device. The air hole(s) 206 of the air curtain device 132 may be facing the air baffle 502 and may be contained within the space defined by the air baffle 502.

The positive-pressure gas flow 202 may be provided from the air hole(s) 206 and into the air baffle 502. The sidewalls 504 and the backside surface 208 of the air baffle 502 contain the positive-pressure gas flow 202 and inhibit diffusion or lateral distribution of the positive-pressure gas flow 202. This enables the positive-pressure gas flow 202 to be more effectively directed in a particular direction, such as toward a bottom surface of a wafer stack 108.

As indicated above, FIG. 5 is provided as an example. Other examples may differ from what is described with regard to FIG. 5.

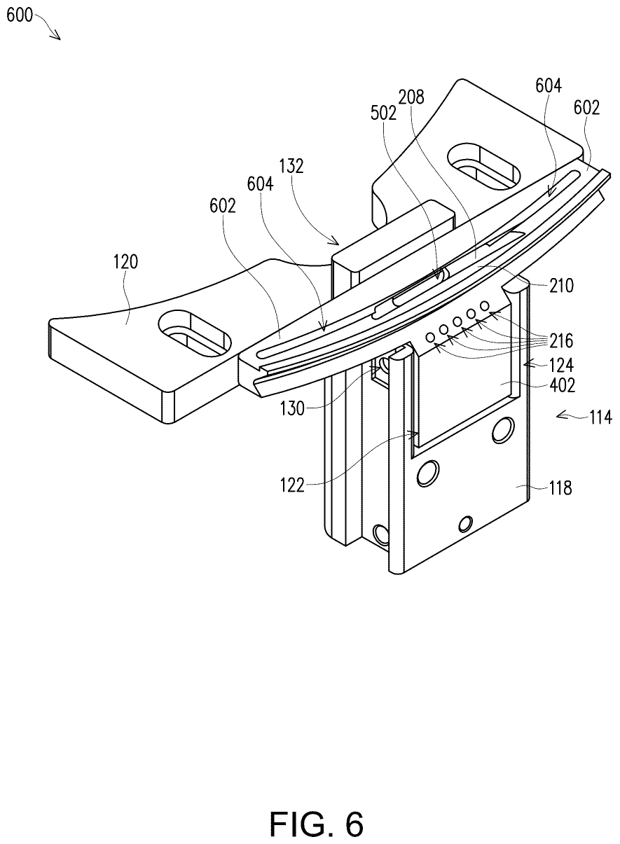

FIG. 6 is a diagram of an example implementation 600 of the vacuum device 124 of the splash prevention system 114 described herein. As shown in FIG. 6, the example implementation 600 of the vacuum device 124 is similar to the example implementation 500 of the vacuum device 124 illustrated in FIG. 5. However, the example implementation 600 of the vacuum device 124 includes extension wings 602 that extend laterally outward from the air baffle 502. The extension wings 602 each include a groove 604 through which the positive-pressure gas flow 202 is to be distributed. The extension wings 602 provide for greater lateral distribution of the positive-pressure gas flow 202 compared to the confinement provided by the sidewalls 504 in the example implementation 500 of vacuum device 124. The positive-pressure gas flow 202 may flow from the air baffle 502 and into the groove 604.

As indicated above, FIG. 6 is provided as an example. Other examples may differ from what is described with regard to FIG. 6.

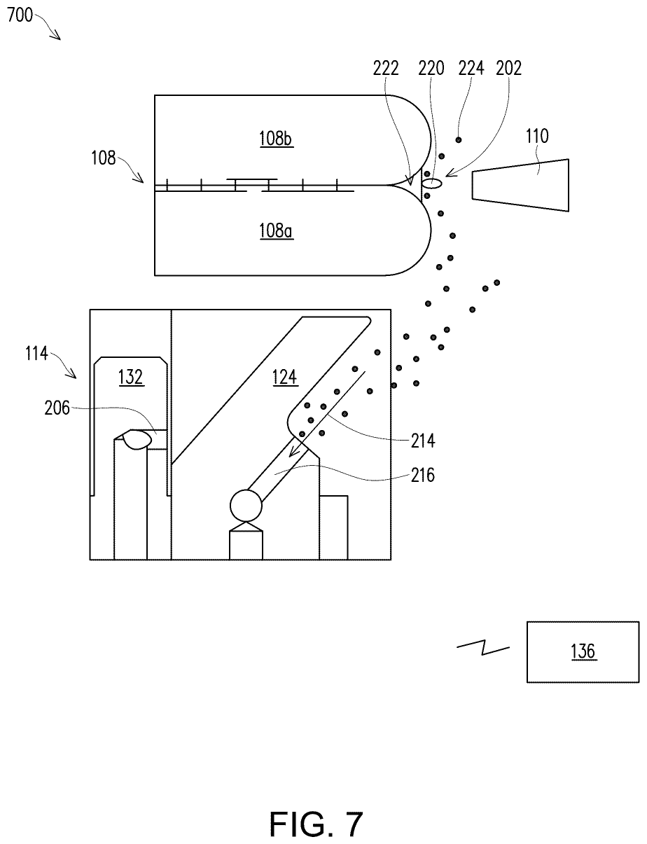

FIG. 7 illustrates an example implementation 700 of an edge sealing operation described herein. The edge sealing operation may be performed using the semiconductor processing tool 100 described herein. The edge sealing operation may be performed to dispense a sealant into a groove around a perimeter of a wafer stack 108 positioned on a chuck 106 in a processing chamber 102 of the semiconductor processing tool 100.

As shown in FIG. 7, the example implementation 700 of the edge sealing operation is similar to the example implementation 200 of the edge sealing operation illustrated and described in connection with FIG. 2. However, in the example implementation 700, only the vacuum device 124 of the splash prevention system 114 is used to pull or suck errant sealant particles 224 away from a bottom surface of the wafer stack (e.g., and into the vacuum hole(s) 216) using the negative-pressure gas flow 214. The use of the air curtain device 132 is omitted in the example implementation 700. This may simplify the operation of the splash prevention system 114 while still providing effective control over the flow of errant sealant particles 224, whereas the use of both the vacuum device 124 and the air curtain device 132 (as in the example implementation 200) may provide increased effectiveness in controlling the flow of errant sealant particles 224.

As indicated above, FIG. 7 is provided as an example. Other examples may differ from what is described with regard to FIG. 7.

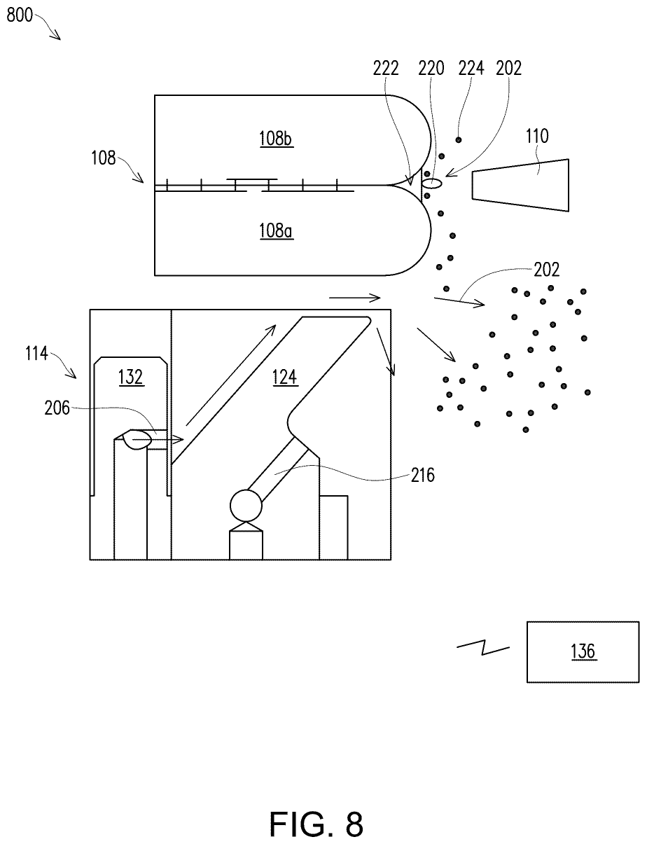

FIG. 8 illustrates an example implementation 800 of an edge sealing operation described herein. The edge sealing operation may be performed using the semiconductor processing tool 100 described herein. The edge sealing operation may be performed to dispense a sealant into a groove around a perimeter of a wafer stack 108 positioned on a chuck 106 in a processing chamber 102 of the semiconductor processing tool 100.

As shown in FIG. 8, the example implementation 800 of the edge sealing operation is similar to the example implementation 200 of the edge sealing operation illustrated and described in connection with FIG. 2. However, in the example implementation 800, only the air curtain device 132 of the splash prevention system 114 is used to push or dispel errant sealant particles 224 away from a bottom surface of the wafer stack 108 using the positive-pressure gas flow 202. The use of the vacuum device 124 to provide the negative-pressure gas flow 214 is omitted in the example implementation 800. This may simplify the operation of the splash prevention system 114 while still providing effective control over the flow of errant sealant particles 224, whereas the use of both the vacuum device 124 and the air curtain device 132 (as in the example implementation 200) may provide increased effectiveness in controlling the flow of errant sealant particles 224.

As indicated above, FIG. 8 is provided as an example. Other examples may differ from what is described with regard to FIG. 8.

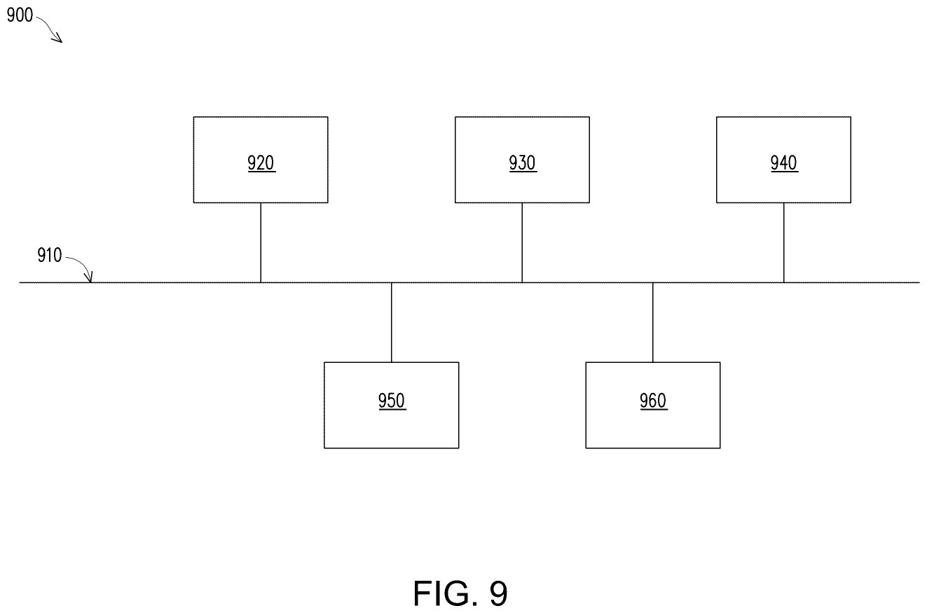

FIG. 9 is a diagram of example components of a device 900 described herein. The device 900 may correspond to the controller 136 of the splash prevention system 114 and/or of the semiconductor processing tool 100. In some implementations, the splash prevention system 114 and/or the semiconductor processing tool 100 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

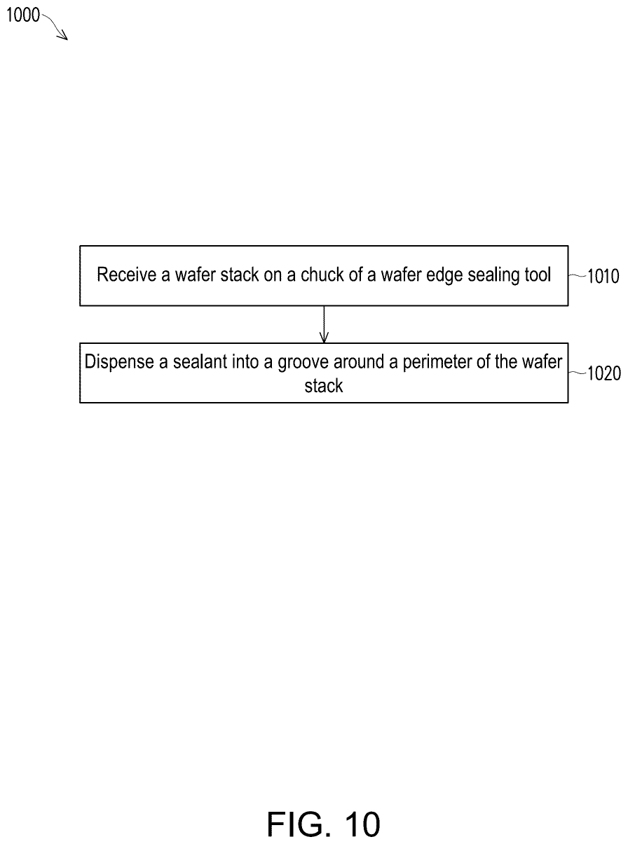

FIG. 10 is a flowchart of an example process 1000 associated with performing an edge sealing operation described herein. In some implementations, one or more process blocks of FIG. 10 are performed by a wafer edge sealing tool (e.g., the semiconductor processing tool 100). In some implementations, one or more process blocks of FIG. 10 are performed by another device or a group of devices separate from or including the wafer edge sealing tool, such as a splash prevention system (e.g., a splash prevention system 114). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include receiving a wafer stack on a chuck of a wafer edge sealing tool (block 1010). For example, the wafer edge sealing tool may receive a wafer stack (e.g., a wafer stack 108 that includes stacked substrates 102a and 102b) on a chuck (e.g., a chuck 106) of a wafer edge sealing tool (e.g., the semiconductor processing tool 100), as described herein.

As further shown in FIG. 10, process 1000 may include dispensing a sealant into a groove around a perimeter of the wafer stack (block 1020). For example, the wafer edge sealing tool may dispense a sealant (e.g., a sealant 220) into a groove (e.g., a groove 222) around a perimeter of the wafer stack, as described herein. In some implementations, a vacuum device (e.g., a vacuum device 124), of a splash prevention system (e.g., a splash prevention system 114) of the wafer edge sealing tool, pulls errant sealant particles (e.g., sealant particles 224) away from a bottom surface of the wafer stack using a negative-pressure gas flow (e.g., a negative-pressure gas flow 214). In some implementations, an air curtain device (e.g., an air curtain device 132), of the splash prevention system, pushes errant sealant particles (e.g., sealant particles 224) away from a bottom surface of the wafer stack using a positive-pressure gas flow (e.g., a positive-pressure gas flow 202).

Process 1000 may include additional implementations, such as any single implementation or any combination of implementations described below and/or in connection with one or more other processes described elsewhere herein.

In a first implementation, the vacuum device is positioned under the wafer stack and is located inward from the perimeter of the wafer stack by a distance (e.g., a dimension D2).

In a second implementation, alone or in combination with the first implementation, the vacuum device is positioned under the wafer stack and is spaced apart from the bottom surface of the wafer stack by a distance (e.g., a dimension D1).

In a third implementation, alone or in combination with one or more of the first and second implementations, the distance is adjusted, during dispensing the sealant, using an adjustment member (e.g., an adjustment member 126) coupled to the vacuum device.

In a fourth implementation, alone or in combination with one or more of the first through third implementations, the adjustment member extends through a main body (e.g., a main body 118) of the splash prevention system, and the adjustment member moves the vacuum device within a recess (e.g., a recess 122) in the main body.

In a fifth implementation, alone or in combination with one or more of the first through fourth implementations, the vacuum device pulls the errant sealant particles into one or more vacuum holes (e.g., vacuum holes 216) located on the vacuum device.

In a sixth implementation, alone or in combination with one or more of the first through fifth implementations, the negative-pressure gas flow is provided through the one or more vacuum holes.

In a seventh implementation, alone or in combination with one or more of the first through sixth implementations, the air curtain device provides the positive-pressure gas flow outward away from the perimeter of the wafer stack.

In an eighth implementation, alone or in combination with one or more of the first through sixth implementations, the air curtain device provides the positive-pressure gas flow toward the bottom surface of the wafer stack.

In a ninth implementation, alone or in combination with one or more of the first through eighth implementations, the air curtain device provides the positive-pressure gas flow along a baffle device (e.g., a top surface 210 of the vacuum device 124) of the splash prevention system toward the bottom surface of the wafer stack.

In a tenth implementation, alone or in combination with one or more of the first through ninth implementations, the air curtain device provides the positive-pressure gas flow between the baffle device and the bottom surface of the wafer stack (e.g., through a gap 212 between the baffle device and the bottom surface of the wafer stack).

In an eleventh implementation, alone or in combination with one or more of the first through tenth implementations, the air curtain device provides the positive-pressure gas flow from a gas inlet (e.g., a gas inlet 134), through a gas supply line (e.g., a gas supply line 204) in a main body of the splash prevention system, and from one or more air holes (e.g., air holes 206) in the air curtain device.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a splash prevention system for use with a wafer edge sealing tool includes one or more devices that are configured to prevent, minimize, and/or reduce the likelihood of errant sealant particles landing on a top and/or a bottom surface of a wafer stack during an edge sealing operation. The wafer stack may be placed on a chuck in a processing chamber of the wafer edge sealing tool, and an injector nozzle of the wafer edge sealing tool may dispense the sealant into the groove around the wafer stack as the chuck is used to rotate the wafer stack. While the sealant is being dispensed into the groove, a vacuum device of the splash prevention system may provide a negative-pressure gas flow at the edge of the wafer stack, and the negative-pressure gas flow is used to collect errant sealant particles before the errant sealant particles land on the top and/or the bottom surface of the wafer stack. Additionally and/or alternatively, while the sealant is being dispensed into the groove, an air curtain device may provide a positive-pressure gas flow at the edge of the wafer stack, and the positive-pressure gas flow may be used to dispel errant sealant particles away from the edge of the wafer stack before the errant sealant particles land on the top and/or the bottom surface of the wafer stack. In this way, the negative-pressure gas flow provided by the vacuum device of the splash prevention system and/or the positive-pressure gas flow provided by the air curtain device of the splash prevention system reduce the likelihood of (and/or the amount of) sealant particles landing on the top and/or the bottom surfaces of the wafer stack. This reduces the likelihood of formation of defects in the integrated circuit die product formed on the substrates of the wafer stack, and/or reduces the likelihood of process defects occurring in subsequent processes performed for the wafer stack. Accordingly, the splash prevention system described herein may increase the yield of integrated circuit die product formed on the substrates of the wafer stack.

As described in greater detail above, some implementations described herein provide a method. The method includes receiving a wafer stack on a chuck of a wafer edge sealing tool. The method includes dispensing a sealant into a groove around a perimeter of the wafer stack, where a device, of a splash prevention system of the wafer edge sealing tool, pulls errant sealant particles away from a bottom surface of the wafer stack using a negative-pressure gas flow.

As described in greater detail above, some implementations described herein provide a method. The method includes receiving a wafer stack on a chuck of a wafer edge sealing tool. The method includes dispensing a sealant into a groove around a perimeter of the wafer stack, where a device, of a splash prevention system of the wafer edge sealing tool, pushes errant sealant particles away from a bottom surface of the wafer stack using a positive-pressure gas flow.

As described in greater detail above, some implementations described herein provide a splash prevention system, for use in a wafer edge sealing tool. The splash prevention system includes a vacuum device. The vacuum device includes a plurality of vacuum holes through which the vacuum device is to receive sealant particles using a negative-pressure gas flow. The splash prevention system includes an air curtain device facing a backside surface of the vacuum device. The air curtain device includes a plurality of air holes through which the air curtain device is to dispel the sealant particles using a positive-pressure gas flow.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a wafer stack on a chuck of a wafer edge sealing tool; and
dispensing a sealant into a groove around a perimeter of the wafer stack,
wherein a device, of a splash prevention system of the wafer edge sealing tool, pulls errant sealant particles away from a bottom surface of the wafer stack using a negative-pressure gas flow.

2. The method of claim 1, wherein the device is positioned under the wafer stack and is located inward from the perimeter of the wafer stack by a distance.

3. The method of claim 1, wherein the device is positioned under the wafer stack and is spaced apart from the bottom surface of the wafer stack by a distance.

4. The method of claim 3, wherein the distance is adjusted, during dispensing the sealant, using an adjustment member coupled to the vacuum device.

5. The method of claim 4, wherein the adjustment member extends through a main body of the splash prevention system; and
wherein the adjustment member moves the device within a recess in the main body.

6. The method of claim 1, wherein the vacuum device pulls the errant sealant particles into one or more device holes located on the device.

7. The method of claim 6, wherein the negative-pressure gas flow is provided through the one or more device holes.

8. A method, comprising:
receiving a wafer stack on a chuck of a wafer edge sealing tool; and
dispensing a sealant into a groove around a perimeter of the wafer stack,
wherein a device, of a splash prevention system of the wafer edge sealing tool, pushes errant sealant particles away from a bottom surface of the wafer stack using a positive-pressure gas flow.

9. The method of claim 8, wherein the device provides the positive-pressure gas flow outward away from the perimeter of the wafer stack.

10. The method of claim 8, wherein the device provides the positive-pressure gas flow toward the bottom surface of the wafer stack.

11. The method of claim 8, wherein the device provides the positive-pressure gas flow along a baffle device of the splash prevention system toward the bottom surface of the wafer stack.

12. The method of claim 11, wherein the device provides the positive-pressure gas flow between the baffle device and the bottom surface of the wafer stack.

13. The method of claim 8, wherein the device provides the positive-pressure gas flow from a gas inlet, through a gas supply line in a main body of the splash prevention system, and from one or more holes in the device.

14. A splash prevention system, for use in a wafer edge sealing tool, comprising:
a vacuum device comprising a plurality of vacuum holes through which the vacuum device is to receive sealant particles using a negative-pressure gas flow; and
an air curtain device facing a backside surface of the vacuum device, comprising a plurality of air holes through which the air curtain device is to dispel the sealant particles using a positive-pressure gas flow.

15. The splash prevention system of claim 14, wherein the splash prevention system further comprises:
a main body,
wherein the air curtain device extends from the main body, and
wherein the vacuum device is configured to be movable within a recess in the main body.

16. The splash prevention system of claim 15, wherein the splash prevention system further comprises:
a mounting flange, coupled to the main body, configured to be mounted to a top surface of a base of the wafer edge sealing tool.

17. The splash prevention system of claim 14, wherein the backside surface of the vacuum device is oriented at an acute angle relative to a frontside surface of the air curtain device.

18. The splash prevention system of claim 14, wherein the vacuum device further comprises:
sidewalls on opposing sides of the backside surface of the vacuum device,
wherein the sidewalls extend away from the backside surface and toward a frontside surface of the air curtain device.

19. The splash prevention system of claim 18, wherein the sidewalls and the backside surface of the vacuum device define an air baffle through which the positive-pressure gas flow is to flow; and
wherein the plurality of air holes of the air curtain device are facing the air baffle.

20. The splash prevention system of claim 19, wherein the vacuum device further comprises:
extension wings that extend laterally outward from the air baffle,
wherein the extension wings comprise grooves through which the positive-pressure gas flow is to be distributed.
